(19) United States
(12) Patent Application Publication
(10) Pub. No.: US 2020/0227895 A1
(43) Pub. Date: Jul. 16, 2020

(54) SEMICONDUCTOR LASER ELEMENT AND SEMICONDUCTOR LASER DEVICE

(71) Applicant: PANASONIC CORPORATION, Osaka (JP)

(72) Inventors: Shinichi TAKIGAWA, Osaka (JP); Shinichiro NOZAKI, Osaka (JP)

(21) Appl. No.: 16/633,535

(22) PCT Filed: Jul. 10, 2018
(86) PCT No.: PCT/JP2018/025951

§ 371 Date: Jan. 23, 2020

(30) Foreign Application Priority Data
Jul. 26, 2017 (JP) 2017-144416

(51) Int. Cl. H01S 5/40; H01S 5/22; H01S 5/024

(52) U.S. Cl. CPC H01S 5/4087; H01S 5/22; H01S 5/4043; H01S 5/02469; H01S 5/02423

(57) ABSTRACT

Provided is a semiconductor laser element including: a substrate; and a laser array section located above the substrate and having a plurality of light emitting parts which are arranged next to each other and which emit laser beams, wherein when the wavelengths of the laser beams respectively emitted from the plurality of light emitting parts are plotted in correspondence with the positions of the plurality of light emitting parts, among a plurality of points respectively corresponding to the wavelengths plotted, the point with an extreme value is not located at a position corresponding to the center of the laser array section and is located at a position corresponding to a place separated from the center of the laser array section.

### TECHNICAL FIELD

The present disclosure relates to a semiconductor laser element and a semiconductor laser device.

The present application is a patent application subject to Industrial Technology Enhancement Act, Article 19 on a sponsored research “Development of advanced laser processing with Intelligence based on high-brightness and high-efficiency next-generation laser technologies (TACMI project). Development of GaN-based high-power and high-beam quality laser diodes for high-efficiency laser processing” FY2016 Annual Report conducted by New Energy and Industrial Technology Development Organization.

### BACKGROUND ART

Semiconductor laser elements have advantages of long life, high efficiency, a compact size, etc., and therefore have been in use as light sources for various applications including image display devices such as projectors or displays. For example, the semiconductor laser elements have been increasingly used in recent years for projectors, such as a theater or projection mapping in a large hall, that project a video on a large screen.

There are demands on the semiconductor laser elements used in projectors for achieving higher output in which optical output largely exceeds one watt, for example, a high output of several tends of watts or more. However, it is difficult to provide high output with a single laser beam. Thus, for the purpose of achieving high output, a semiconductor laser array device having a plurality of semiconductor laser elements arranged next to each other or a semiconductor laser element having a plurality of emitters (light emitting parts) is used.

Laser beams typically have high coherence, and thus upon overlapping of two laser beams of the same wavelengths on a given surface, a brightness difference may arise due to a phase difference therebetween and glare (temporal brightness fluctuation) may occur due to the fluctuation of the phase difference. The occurrence of such a brightness difference and glare consequently deteriorates the image quality when the semiconductor laser element is used as a light source for image display in particular.

In the semiconductor laser element having a plurality of emitters in particular, laser beams respectively emitted from the emitters are proximate to each other, so that the laser beams are likely to interfere with each other. Thus, the use of such a semiconductor laser element as a light source of a projector causes brightness non-uniformity and shading (interference fringes) on an image projected on a screen, which generates noise so-called speckle noise.

Such speckle noise is generated due to the interference of laser beams of the same wavelengths. Thus, Patent Literature (PTL) 1 suggests the following two methods to reduce the speckle noise by varying the wavelengths of the plurality of laser beams.

As a first method, PTL 1 discloses in FIG. 5 that an interval between emitters which are included in a plurality of emitters of a laser array section and which are located near a central part is reduced. Consequently, the heat density of the laser array section near the central part increases, which therefore makes it possible to increase the temperature of the laser array section near the central part while reducing the temperature of the laser array section at an end part. The oscillation wavelength of the laser beam increases with an increase in the temperature, and thus adopting this method increases the oscillation wavelength of the laser beam emitted from each emitter in the laser array section with an increase in a distance from the end part to the center in accordance with a temperature distribution. As a result, even when the laser beams emitted from the plurality of emitters overlap, the wavelengths of the aforementioned plurality of emitters are mutually different, thus making it possible to suppress the speckle noise.

As the second method, PTL 1 also discloses in FIG. 11 that the interval between the emitters at one of end parts (for example, the left end part) of the laser array section is reduced while the interval between the emitters at the other end part (for example, the right end part) is increased. Consequently, the heat density at the edge of one of the end parts (the left end part) becomes greater than the heat density at the other end part (the right end part), which therefore makes it possible to increase the temperature at one of the end parts (the left end part) of the laser array section while reducing the temperature at the other end part (the right end part). As a result, the speckle noise can be suppressed as is the case with the first method.

### CITATION LIST

### Patent Literatures

PTL 1: Japanese Unexamined Patent Application Publication No. 2008-205342

### SUMMARY OF THE INVENTION

### Technical Problems

However, with the first method, the laser beam emitted from the emitter at the center of the laser array section has the greatest wavelength and a wavelength variation in horizontal symmetry with respect to the central axis of the laser array section, as illustrated in FIG. 7 of PTL 1. In this case, as a result of the presence of the emitter in the horizontal symmetry with respect to the center of the laser array section, the two laser beams of the same wavelengths are present near the central part of the laser array section, which still leads to a risk that the two laser beams interfere with each other near the central part. Thus, the use of such a semiconductor laser element having a laser array section as a light source of a projector causes the interference between the two laser beams near the center of a screen surface to which an observer (for example, a person who watches a movie or the like) pays the greatest attention, so that the speckle noise near the center of the screen surface is likely to become conspicuous. That is, the observer is likely to sense the speckle noise.

On the other hand, with the second method, of the plurality of laser beams emitted from the laser array section, the laser beam of the greatest wavelength corresponds to the end part of the screen surface and thus the speckle noise is less likely to be conspicuous. However, with the second method, the temperature distribution (wavelength distribution) monotonously increases or monotonously decreases, so that, of the plurality of laser beams emitted from the laser array section, the laser beam of the greatest wavelength and the laser beam of the smallest wavelength have a larger wavelength difference than those of the first method (about two-fold increase compared to that of the first method). Thus, even when the laser array section emits red laser beams, a large number of red laser beams with different chromaticity (wavelengths) are included, which deteriorates the color purity. Thus, the beauty of a video is damaged.

The present disclosure has been made to solve such problems, and it is an object of the present disclosure to provide a semiconductor laser element and a semiconductor laser device capable of emitting laser beams without conspicuous speckle noise (in other words, spatial and temporal fluctuation of luminance) and without color purity (in other words, wavelength purity) deterioration.

### Solutions to Problems

To address the object described above, a semiconductor laser element according to one aspect of the present disclosure includes: a substrate; and a laser array section located above the substrate and having a plurality of light emitting parts which are arranged next to each other and which emit laser beams, wherein when the wavelengths of the laser beams respectively emitted from the plurality of light emitting parts are plotted in correspondence with the positions of the plurality of light emitting parts, among a plurality of points respectively corresponding to the wavelengths plotted, the point with an extreme value is not located at a position corresponding to the center of the laser array section and is located at a position corresponding to a place separated from the center of the laser array section.

Here, the points respectively corresponding to the wavelengths of the plurality of laser beams plotted include extreme values refers to a state in which λ1 and λ3≤λ2 or λ1 and λ3≥λ2 where the wavelengths of the three laser beams emitted from the three continuously arrayed emitters are λ1, λ2, and λ3 in order. Specifically, where a line linking together a point indicating λ1 and a point indicating λ2 is defined as a first line and a line linking together the point indicating λ2 and a point indicating λ3 is defined as a second line, which refers to a case where the inclination of the first line is positive and the inclination of the second line is negative or a case where the inclination of the first line is negative and the inclination of the second line is positive. Note that λ1 and λ3 sandwiching λ2 are likely to have almost the same values which causes speckle noise sensible by a human (that is, the laser beams are likely to interfere with each other).

In the semiconductor laser element according to one aspect of the present disclosure, of the plurality of points respectively corresponding to the wavelengths plotted, the point with the extreme value is not located at the position corresponding to the center of the laser array section and is located at the position corresponding to the place separated from the center of the laser array section.

As described above, removing the extreme value of the wavelength of the laser beam from the center of the laser array section removes the interference of the laser beam at a central part of a visual field to which a human pays the greatest attention. Consequently, the human hardly senses the speckle noise.

Further, since the extreme value of the wavelength of the laser beam is located at the place separated from the center of the laser array section, it is possible to reduce a difference between a maximum value and a minimum value of the wavelengths of the plurality of laser beams emitted from the plurality of light emitting parts. Consequently, it is possible to suppress color purity deterioration of the laser beams emitted from the laser array section.

Therefore, it is possible to realize a semiconductor laser element capable of emitting laser beam without conspicuous speckle noise and without color purity deterioration.

In the semiconductor laser element according one aspect of the present disclosure, intervals between two adjacent light emitting parts included in the plurality of light emitting parts may include different lengths.

As described above, as a result of varying the interval between the two adjacent light emitting parts included in the plurality of light emitting parts depending on the position of the laser array section, heat is likely to remain at a place where the interval between the light emitting parts is short while heat dissipation is promoted at a place where the interval between the light emitting parts is large, thus making it possible to modulate a temperature distribution. Through the temperature distribution modulation, a distribution of oscillation wavelengths of the laser beams modulates. Therefore, the point where a value of the wavelength variation of the laser beam is extreme is not located at the position corresponding to the center of the laser array section and is located at the position corresponding to the place separated from the center of the laser array section.

In the semiconductor laser element according to one aspect of the present disclosure, respective widths of the plurality of light emitting parts may include different lengths.

The effective refractive index (Neff) of the waveguide varies depending on the width of the light emitting part. More specifically, an increase in the width of the light emitting part increases the effective refractive index while a decrease in the width of the light emitting part decreases the effective refractive index. Consequently, the distribution of the oscillation wavelengths of the laser beams can be modulated by modulating the widths of the light emitting parts with the widths of the plurality of light emitting parts varied depending on the position of the laser array section. Therefore, the point where a value of the wavelength variation of the laser beam is extreme is not located at the position corresponding to the center of the laser array section and is located at the position corresponding to the place separated from the center of the laser array section.

In the semiconductor laser element according to one aspect of the present disclosure, the substrate may have a plurality of different off angles in correspondence with the plurality of light emitting parts.

As described above, providing the substrate with the plurality of different off angles for the plurality of light emitting parts, respectively, can provide different band gaps of an active layer for the respective light emitting parts. Consequently, the oscillation wavelength of the laser beam modulates for each light emitting part. Therefore, the point where a value of the wavelength variation of the laser beam is extreme is not located at the position corresponding to the center of the laser array section and is located at the position corresponding to the place separated from the center of the laser array section.

In the semiconductor laser element according to one aspect of the present disclosure, the laser array section may have a ridge waveguide structure having a plurality of ridge parts respectively corresponding to the plurality of light emitting parts, and inclination angles of the plurality of ridge parts may include different angles.

The effective refractive index (Neff) of the waveguide varies depending on the inclination angle of the ridge part. More specifically, for the same ridge width, an increase in the inclination angle of the ridge part widens the effective width of the light emitting part and thereby increases the effective refractive index while a decrease in the inclination angle of the ridge part narrows the effective width of the light emitting part and thereby decreases the effective refractive index. Consequently, the distribution of the oscillation wavelengths of the laser beams can be modulated by modulating the effective widths of the light emitting parts while providing mutually different inclination angles for the plurality of ridge parts. Therefore, the point where a value of the wavelength variation of the laser beam is extreme is not located at the position corresponding to the center of the laser array section and is located at the position corresponding to the place separated from the center of the laser array section.

A semiconductor laser device according to another aspect of the present disclosure includes: a substrate; a laser array section located above the substrate and having a plurality of light emitting parts which are arranged next to each other and which emit laser beams; and a water-cooled heat sink which cools the laser array section, wherein when the wavelengths of the laser beams respectively emitted from the plurality of light emitting parts are plotted in correspondence with the positions of the plurality of light emitting parts, among a plurality of points respectively corresponding to the wavelengths plotted, the point with an extreme value is not located at a position corresponding to the center of the laser array section and is located at a position corresponding to a place separated from the center of the laser array section.

The cooling water flowing through the water-cooled heat sink has high cooling capability on an inlet side of the cooling water because the temperature of the cooling water is low on the inlet side while the cooling water has low cooling capability on an outlet side of the cooling water because of a temperature increase caused by absorption of heat generated in the light emitting part. Therefore, a place in the laser array section where a greatest amount of heat remains shifts from a central part to the outlet side of the cooling water, which can modulate the temperature distribution of the laser array section. The distribution of the oscillation wavelengths of the laser beams is modulated by the aforementioned temperature distribution modulation. Therefore, the point where a value of the wavelength variation of the laser beam is extreme is not located at the position corresponding to the center of the laser array section and is located at the position corresponding to the place separated from the center of the laser array section.

In the semiconductor laser device according to another aspect of the present disclosure, temperatures of cooling water in the water-cooled heat sink may vary depending on the positions of the plurality of light emitting parts.

Consequently, the distribution of the oscillation wavelengths of the laser beams can easily be modulated for each light emitting part.

In the semiconductor laser device according to another aspect of the present disclosure, the cooling water in the water-cooled heat sink may flow along a direction in which the plurality of light emitting parts are arranged next to each other.

Consequently, the distribution of the oscillation wavelengths of the laser beams can easily be modulated for each light emitting part.

### Advantageous Effect of Invention

It is possible to realize a semiconductor laser element and a semiconductor laser device capable of emitting a plurality of laser beams without conspicuous speckle noise and without color purity deterioration.

### BRIEF DESCRIPTION OF DRAWINGS

FIG. 1 is a perspective view of a semiconductor laser element according to Embodiment 1.

IN FIG. 2, (a) is a diagram illustrating a structure of a laser beam emission end surface in the semiconductor laser element according to Embodiment 1, (b) is a diagram illustrating a temperature distribution of an active layer in the semiconductor laser element according to Embodiment 1, (c) is a diagram illustrating a band gap of the active layer in the semiconductor laser element according to Embodiment 1, and (d) is a diagram illustrating oscillation wavelengths of laser beams emitted from a plurality of emitters in the semiconductor laser element according to Embodiment 1.

FIG. 3 is an enlarged sectional view of the surroundings of a ridge part of the semiconductor laser element according to Embodiment 1.

In FIG. 4, (a) is a diagram illustrating a structure of a laser beam emission end surface in a semiconductor laser element according to Embodiment 2, (b) is a diagram illustrating widths of a plurality of emitters in the semiconductor laser element according to Embodiment 2, (c) is a diagram illustrating effective refractive indices of a waveguide corresponding to the plurality of emitters in the semiconductor laser element according to Embodiment 2, and (d) is a diagram illustrating oscillation wavelengths of laser beams emitted from the plurality of emitters in the semiconductor laser element according to Embodiment 2.

In FIG. 5, (a) is a diagram illustrating a structure of a laser beam emission end surface in a semiconductor laser element according to Embodiment 3, (b) is a diagram illustrating a distribution of substrate off angles in the semiconductor laser element according to Embodiment 3, (c) is a diagram illustrating band gaps of an active layer in the semiconductor laser element according to Embodiment 3, and (d) is a diagram illustrating the oscillation wavelengths of laser beams emitted from a plurality of emitters in the semiconductor laser element according to Embodiment 3.

In FIG. 6, (a) is a diagram illustrating a structure of a laser beam emission end surface in a semiconductor laser element according to Embodiment 4, (b) is a diagram illustrating a distribution of inclination angles of ridge parts in the semiconductor laser element according to Embodiment 4, (c) is a diagram illustrating effective refractive indices of the waveguide corresponding to a plurality of emitters in the semiconductor laser element according to Embodiment 4, and (d) is a diagram illustrating the oscillation wavelengths of laser beams emitted from the plurality of emitters in the semiconductor laser element according to Embodiment 4.

FIG. 7 is a perspective view of a semiconductor laser device according to Embodiment 5.

In FIG. 8, (a) is a diagram illustrating a structure of a laser beam emission end surface in a semiconductor laser device according to Embodiment 5, (b) is a diagram illustrating a temperature distribution of cooling water in the semiconductor laser device according to Embodiment 5, (c) is a diagram illustrating a temperature distribution of an active layer in the semiconductor laser device according to Embodiment 5, and (d) is a diagram illustrating the oscillation wavelengths of laser beams emitted from five emitters in the semiconductor laser device according to Embodiment 5.

FIG. 9 is a diagram illustrating a direction of cooling water flow in the semiconductor laser device according to Embodiment 5.

FIG. 10 is a schematic diagram of a projector according to Embodiment 6.

FIG. 11 is a perspective view of a semiconductor laser element according to Variation 1.

FIG. 12 is an enlarged sectional view of the surroundings of a ridge part of the semiconductor laser element according to Variation 1.

FIG. 13 is a perspective view of a semiconductor laser element according to Variation 2.

FIG. 14 is an enlarged sectional view of the surroundings of a ridge part of the semiconductor laser element according to Variation 2.

### DESCRIPTION OF EXEMPLARY EMBODIMENTS

Hereinafter, the embodiments of the present disclosure will be described with reference to the drawings. Note that each of the embodiments described below illustrates one detailed preferable example of the present disclosure. Therefore, numerical values, shapes, materials, components, and arrangement positions and connection modes of the components as well as steps (processes), a sequence of the steps, etc. form one example and are not intended to limit the present disclosure in any manner. Therefore, of components in the embodiments described below, those not described in an independent claim indicating the most generic concept of the present disclosure will be described as optional components.

Moreover, each of the figures is a schematic diagram which does not necessarily provides a precise illustration. Therefore, scales do not necessarily match in each figure. Those with substantially the same configurations in each of the figures will be provided with the same numerals and overlapping description of the aforementioned components will be omitted or simplified.

### Embodiment 1

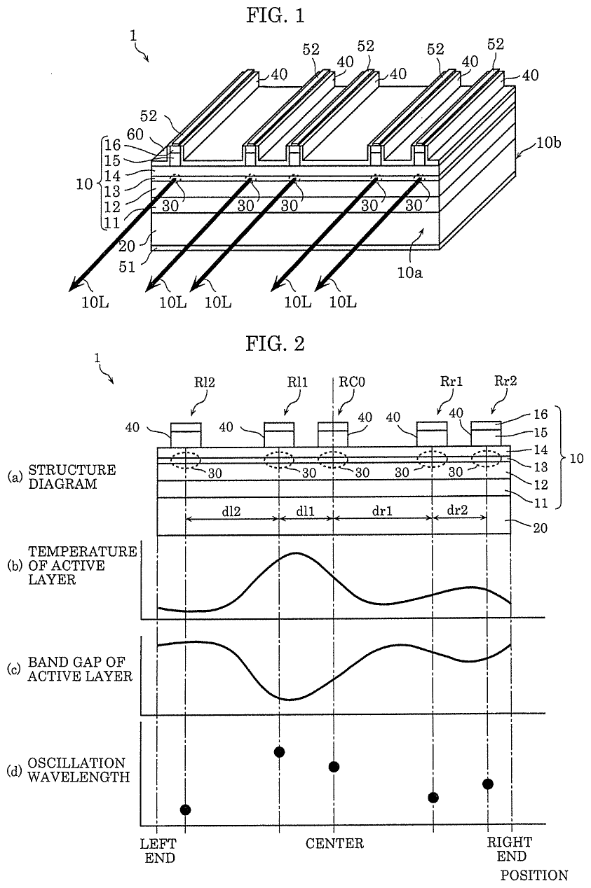

First, a configuration of semiconductor laser element 1 according to Embodiment 1 will be described with reference to FIG. 1. FIG. 1 is a perspective view of semiconductor laser element 1 according to Embodiment 1.

As illustrated in FIG. 1, semiconductor laser element 1 according to the present embodiment is one example of a semiconductor light emitting element, and includes: substrate 20; and laser array section 10 located on substrate 20. A plurality of emitters 30 (light emitting parts) which emit laser beams are arranged next to each other in laser array section 10. That is, semiconductor laser element 1 is a multi-emitter laser including the plurality of emitters 30. Each emitter 30 is a light emitting region which emits a beam as a result of current injection into laser array section 10.

Laser array section 10 is a laminate having first cladding layer 11, first guiding layer 12, active layer 13, second guiding layer 14, second cladding layer 15, and contact layer 16 laminated in order just mentioned. Note that the layer structure of laser array section 10 may be a superlattice structure in which thin films are laminated at the atomic level. Alternatively, the layer structure of laser array section 10 is not limited to the laminate described above, and in addition to the aforementioned layers, for example, a layer for avoiding electronic leakage from active layer 13 (for example, an electronic overflow suppression layer) or a strain relaxation layer may be formed.

Laser array section 10 has a pair of first end surface 10a and second end surface 10b opposing each other in a longitudinal direction of a resonator of semiconductor laser element 1. First end surface 10a is a front end surface from which a laser beam is emitted and second end surface 10b is a rear end surface in the present embodiment. Note that reflection films formed of a dielectric multilayer film may be formed as end surface coating films on first end surface 10a and second end surface 10b. In this case, the reflection film with a low refractive index may be formed on first end surface 10a serving as a light emission end surface while the reflection film with a high refractive index may be formed on second end surface 10b.

Laser array section 10 has a ridge waveguide structure having ridge parts 40. More specifically, laser array section 10 has a plurality of ridge parts 40. Five ridge parts 40 are formed in laser array section 10 in the present embodiment. Second cladding layer 15 and contact layer 16 are separated into a plurality of parts by five ridge parts 40. Each of ridge parts 40 extends linearly in the longitudinal direction of the laser resonator (a laser beam oscillation direction).

Note that ridge parts 40 are formed from a border between second guiding layer 14 and second cladding layer 15 in the present embodiment but ridge parts 40 may be formed from the middle of second guiding layer 14 or second cladding layer 15.

The plurality of ridge parts 40 respectively correspond to the plurality of emitters 30. That is, there is a one-to-one correspondence between emitters 30 and ridge parts 40. In the present embodiment, since five ridge parts 40 are provided in laser array section 10, five emitters 30 are located in laser array section 10.

Five emitters 30 are arrayed linearly along a direction orthogonal to the longitudinal direction of the laser resonator (that is, a width direction of ridge parts 40). That is, five emitters 30 are arrayed in a horizontal direction in laser array section 10.

Further, semiconductor laser element 1 is provided with first electrode 51 and second electrodes 52 for the purpose of current injection into laser array section 10. Fist electrode 51 is an ohmic electrode provided on the rear surface of substrate 20. Second electrode 52 is an ohmic electrode formed in contact with contact layer 16 of each ridge part 40. Note that when substrate 20 is an insulating substrate, first electrode 51 may be formed on the top surface of exposed first cladding layer 11.

Moreover, insulating layer 60 is formed to coat side surfaces of ridge parts 40 and flat parts of ridge parts 40 extending horizontally from the roots of ridge parts 40. The formation of insulating layer 60 can suppress a flow of an injected current into a region between two adjacent ridge parts 40.

In semiconductor laser element 1 configured as described above, upon voltage application to first electrode 51 and second electrodes 52, a current flows between first electrode 51 and second electrodes 52. That is, the current is injected into laser array section 10. The current injected into laser array section 10 flows only to lower parts of ridge parts 40. Consequently, the current is injected into active layer 13 located immediately below ridge parts 40, and electrons and holes are recombined for light emission in active layer 13, whereby emitters 30 are generated.

A beam generated in emitter 30 is confined in a direction perpendicular to the substrate (vertical direction) due to a refractive index difference between first cladding layer 11, first guiding layer 12, active layer 13, second guiding layer 14, second cladding layer 15, and contact layer 16. On the other hand, the beam generated in emitter 30 is confined in a horizontal direction of the substrate (horizontal direction) due to a refractive index difference between an inside of ridge part 40 (second cladding layer 15 and contact layer 16) and an outside of ridge part 40 (insulating layer 60). As described above, semiconductor laser element 1 is a refractive index waveguide semiconductor laser in the present embodiment.

Then the beam generated in emitter 30 reciprocates and resonates between first end surface 10a and second end surface 10b, and as a result of obtaining a gain through the current injection, the aforementioned beam turns into a high-intensity laser beam 10L with equal phases, exiting from first end surface 10a of emitter 30. Since five ridge parts 40 are formed in the present embodiment, laser beam 10L is emitted from each of five emitters 30. That is, five laser beams 10L are emitted from laser array section 10. Note that a point of first end surface 10a at which laser beam 10L is emitted serves as a light emission point of emitter 30.

The oscillation wavelength (emission color) of the laser beam can be adjusted by changing a material of each of the layers of laser array section 10. For example, it is possible to oscillate red, green, and blue laser beams.

Semiconductor laser element 1 according to the present embodiment is configured to emit red laser beams. In this case, semiconductor laser element 1 which emits red laser beams can be provided by using, as substrate 20, a semiconductor substrate formed of a GaAs substrate and forming laser array section 10 by a semiconductor material formed of a group III-V compound semiconductor represented by AlₓGa_{y}In_{1-x-y}As_{z}P_{1-z} (where 0≤x, y, z≤1, and 0≤x+y≤1).

More specifically, an n-type GaAs substrate with a thickness of 80 μm and surface (100) serving as a main surface can be used as substrate 20. In this case, as laser array section 10 formed of an AlGaInP semiconductor material, it is possible to use an n-type cladding layer as first cladding layer 11, use an undoped n-side guiding layer as first guiding layer 12, use an undoped active layer as active layer 13, use an undoped p-side guiding layer as second guiding layer 14, use a p-type cladding layer as second cladding layer 15, and use a p-type contact layer as contact layer 16.

As one example, first cladding layer 11 is formed of n-(Al_{0.6}Ga_{0.4})_{0.5}In_{0.5}P with a film thickness of 1 μm, first guiding layer 12 is formed of u-(Al_{0.4}Ga_{0.6})_{0.5}In_{0.5}P with a film thickness of 0.1 μm, active layer 13 is formed of u-In_{0.5}Ga_{0.5}P with a film thickness of 10 nm, second guiding layer 14 is formed of u-(Al_{0.4}Ga_{0.6})_{0.5}In_{0.5}P with a film thickness of 0.1 μm, second cladding layer 15 is formed of p-(Al_{0.6}Ga_{0.4})_{0.5}In_{0.5}P with a film thickness of 0.5 μm, and contact layer 16 is formed of p-GaAs with a film thickness of 0.1 μm. Note that first electrode 51 is an n-side electrode and second electrodes 52 are p-side electrodes and the both are each formed of a metal material such as Cr, Ti, Ni, Pd, Pt, or Au.

Next, characteristics and a configuration of semiconductor laser element 1 according to the present embodiment will be described based on FIG. 2 while referring to FIG. 1. In FIG. 2, (a) is a structure diagram of a laser beam emission end surface in semiconductor laser element 1 according to Embodiment 1, (b) is a diagram illustrating a temperature distribution of active layer 13 in same semiconductor laser element 1, (c) is a diagram illustrating a band gap of active layer 13 in same semiconductor laser element 1, and (d) is a diagram illustrating the oscillation wavelengths of laser beams emitted from five emitters 30 in same semiconductor laser element 1. Note that in FIG. 2(a), first electrode 51, second electrodes 52, and insulating layer 60 are omitted.

As illustrated in FIGS. 1 and 2(a), laser array section 10 of semiconductor laser element 1 according to the present embodiment is provided with five ridge parts 40. Each of ridge parts 40 is formed by second cladding layer 15 and contact layer 16.

As illustrated in FIG. 2(a), where five ridge parts 40 are ridge part Rl2, ridge part Rl1, ridge part RC0, ridge part Rr1, and ridge part Rr2 from the left end to the right end of laser array section 10, ridge part RC0 is located at the center of laser array section 10.

Intervals between two adjacent ridge parts 40 in the plurality of ridge parts 40 include different lengths in the present embodiment. More specifically since five ridge parts 40 are formed in laser array section 10, four intervals are provided as the intervals between two adjacent ridge parts 40 (ridge intervals). The aforementioned four intervals include: from the left end to the right end of laser array section 10, first interval dl2 (interval between ridge part Rl2 and ridge part Rl1), second interval dl1 (interval between ridge part Rl1 and ridge part RC0), third interval dr1 (interval between ridge part RC0 and ridge part Rr1), and fourth interval dr2 (interval between ridge part Rr1 and ridge part Rr2). The four intervals are different from each other.

As one example, where the width of laser array section 10 (chip width) is 250 μm and the length of the resonator of laser array section 10 is 1 mm, the four intervals between two adjacent ridge parts 40 are dl2=60 μm, dl1=40 μm, dr1=50 μm, and dr2=30 μm. Note that the widths of five ridge parts 40 (ridge widths) are equal, which is 5 μm. The inclination angles of five ridge parts 40 (ridge angles) are all equal.

As described above, although the widths and ridge angles of ridge parts 40 are all equal in the present embodiment, the intervals between two adjacent ridge parts 40 include the different lengths and five ridge parts 40 have four ridge parts Rl2, Rl1, Rr1, and Rr2 arranged in asymmetry with respect to ridge part RC0 at the center.

Moreover, the positions and widths of emitters 30 correspond to the positions and widths of ridge parts 40. Consequently, as is the case with ridge parts 40, two adjacent emitters 30 in the plurality of emitters 30 include different lengths. More specifically, since five emitters 30 are provided in correspondence with five ridge parts 40, there are four intervals between two adjacent emitters 30 (emitter intervals).

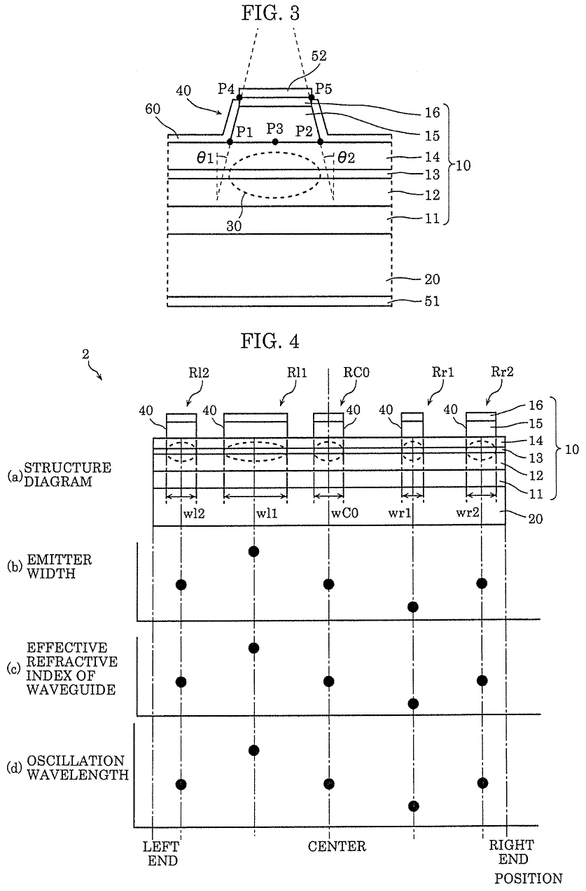

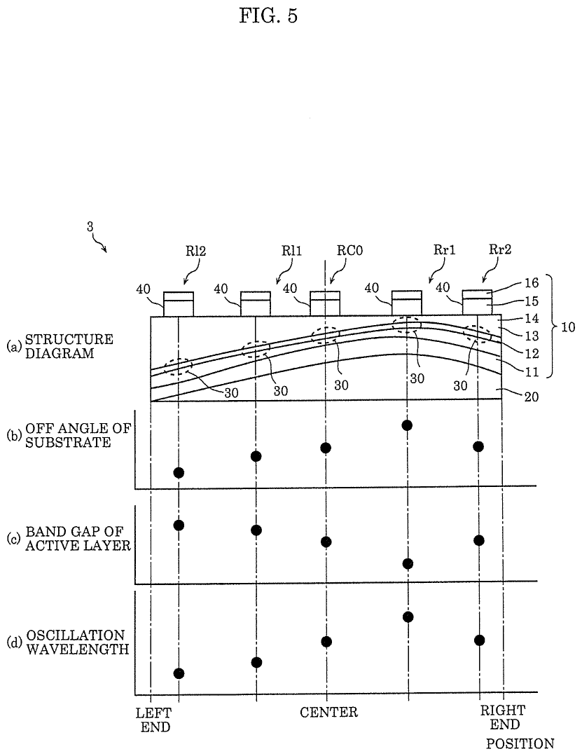

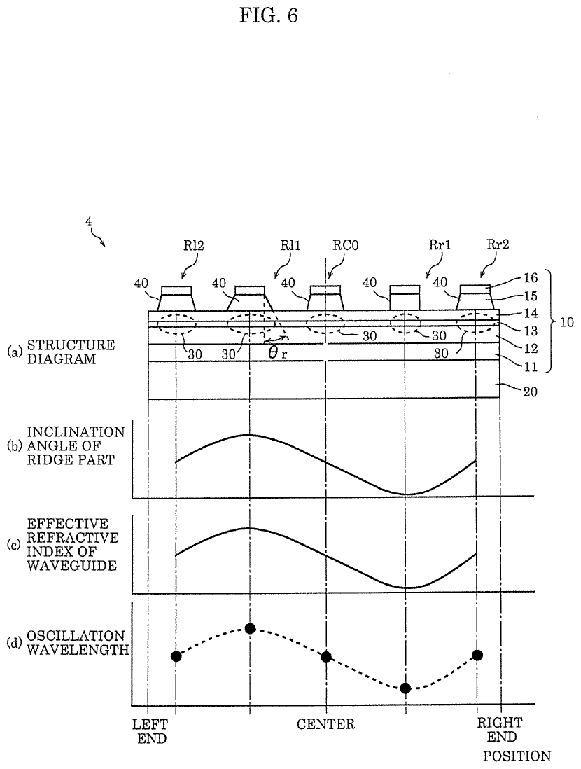

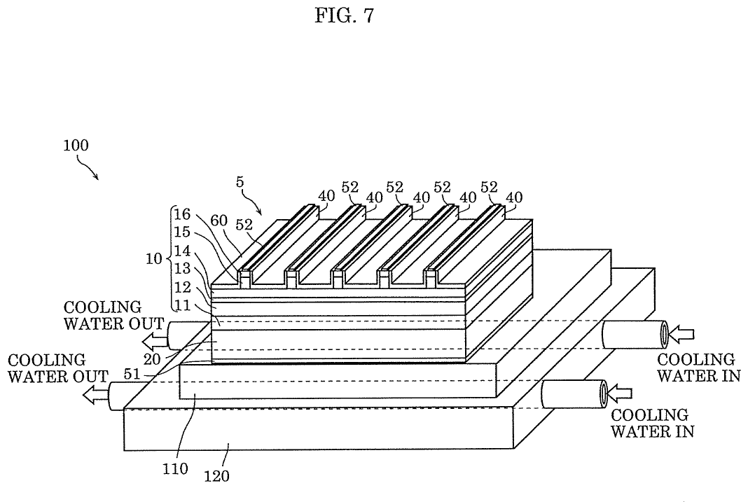

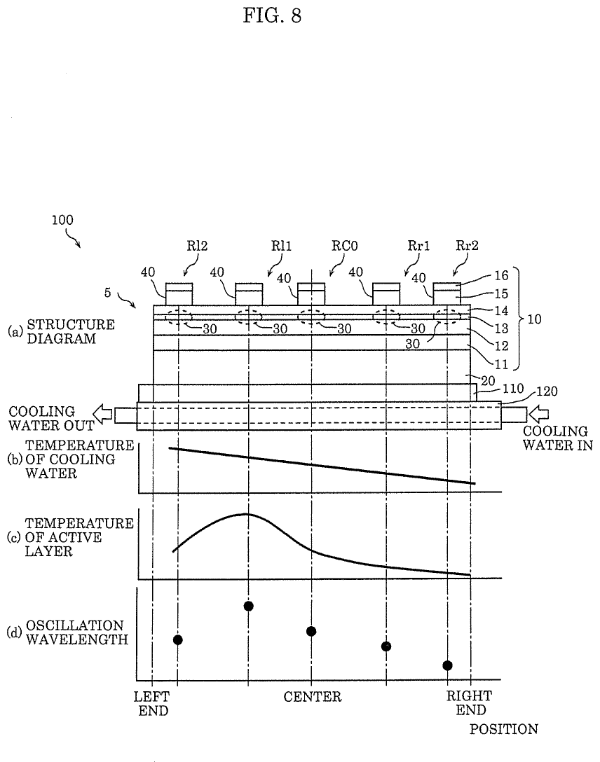

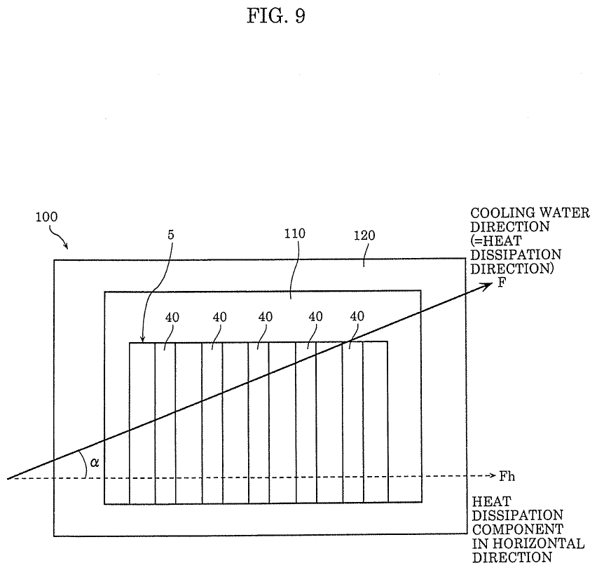

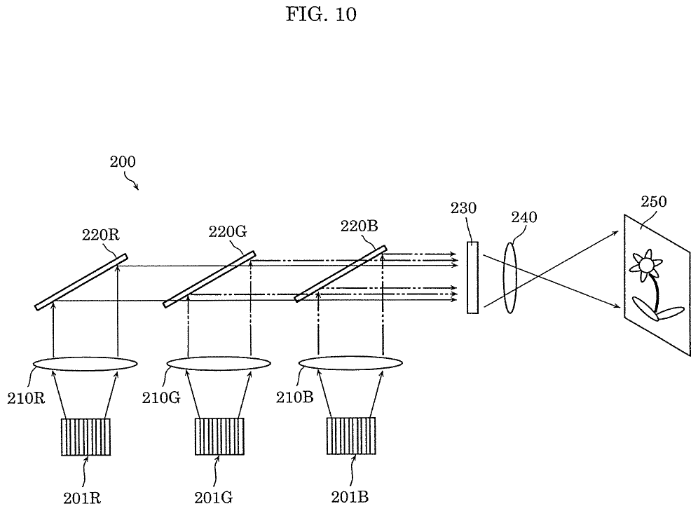

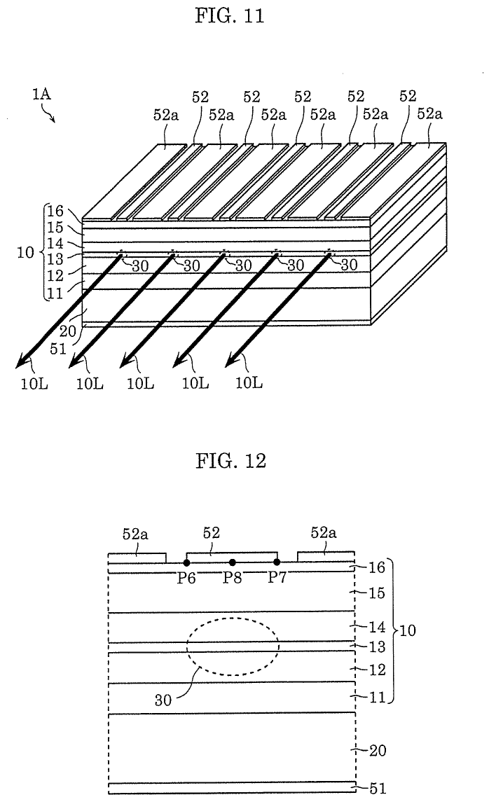

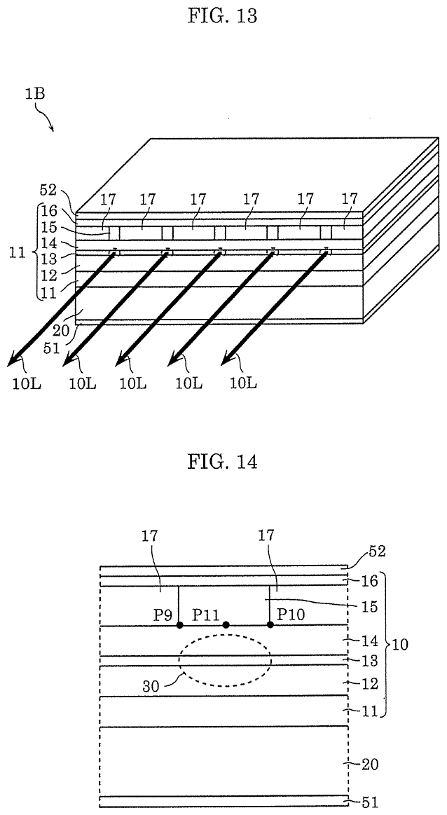

Here, the interval between two adjacent emitters 30 (emitter interval) is a distance linking together middle points of two adjacent emitters 30. Moreover, the middle point of each emitter 30 matches the middle point of each ridge part 40, serving as a middle point of a line linking together right and left corners (right and left points at the root) at a lowermost part of each ridge part 40. More specifically, as illustrated in FIG. 3, where coordinates at the left point at the root of ridge part 40 on the emission end surface are P1(x1, y1) and coordinates at the right point at the root of ridge part 40 on the emission end surface are P2(x2, y2), a point represented by coordinates P3((x1+x2)/2, (y1+y2)/2) serves as the middle point of each ridge part 40 and also the middle point of each emitter 30.

The width of emitter 30 (emitter width) is almost equivalent to the length of a line linking together the right and left corners (the two right and left points at the root) at the lowermost part of ridge part 40. More specifically, the width of emitter 30 in FIG. 3 is a length of a line linking together points P1 and P2 and is thus represented by {(x1−x2)²+(y1−y2)²}^{1/2}.

Since the interval between two adjacent emitters 30 (emitter interval) matches the interval between two adjacent ridge parts 40 (ridge interval), as is the case with the ridge intervals, the four emitter intervals are first interval dl2, second interval dl1, third interval dr1, and fourth interval dr2 which are different from each other.

Moreover, the width of emitter 30 (emitter width) is a length in a direction in which the plurality of emitters 30 are arrayed in a secondary light emission distribution. Therefore, the width of each emitter 30 matches the width of ridge part 40 (ridge width). In the present embodiment, the five emitter widths are 5 μm, i.e., are mutually equal values, as is the case with the ridge widths.

In semiconductor laser element 1 configured as described above, the five emitter intervals are varied depending on the position of laser array section 10. Consequently, heat is likely to remain at a place where the emitter interval is short while heat dissipation is promoted at a place where the emitter interval is large, thus permitting modulation of the temperature distribution.

Second interval dl1 is relatively short in the present embodiment and thus the heat dissipation in emitters 30 corresponding to ridge part Rl1 and ridge part RC0 is low. Moreover, fourth interval dr2 is also relatively short and thus the heat dissipation in emitters 30 corresponding to ridge parts Rr1 and Rr2 is also low.

Moreover, ridge parts Rr1 and Rr2 are located on a side closer to the end part of laser array section 10 than ridge parts Rr1 and RC0. Thus, the heat dissipation performance of emitters 30 corresponding to ridge parts Rr1 and Rr2 becomes better than the heat dissipation performance of emitters 30 corresponding to ridge parts Rl1 and RC0.

As a result, the temperature distribution of active layer 13 modulates. More specifically, the temperature distribution of active layer 13 varies as illustrated in FIG. 2(b). An increases in the temperature of active layer 13 decreases the band gap of a material of active layer 13, and thus the band gap of active layer 13 modulates in accordance with the temperature distribution of active layer 13 and varies as illustrated in FIG. 2(c).

The oscillation wavelength of the laser beam here increases with a decrease in the band gap of active layer 13. Thus, when the oscillation wavelengths of the laser beams respectively emitted from five emitters 30 are plotted in correspondence with the positions of five emitters 30, the oscillation wavelengths of the laser beams vary in accordance with the distribution of the band gaps of active layer 13 as illustrated in FIG. 2(d). That is, the oscillation wavelengths of the five laser beams show an asymmetrical distribution.

More specifically, emitted from five emitters 30 corresponding to five ridge parts Rl2, Rl1, RC0, Rr1, and Rr2 are red laser beams of 630.0 nm, 632.5 nm, 632.0 nm, 631.0 nm, and 631.5 nm in order from the left end to the right end of laser array section 10.

As described above, the wavelength variation of the five laser beams is caused by a difference in the intervals between five ridge parts 40 (that is, the intervals between the plurality of emitters 30) in the present embodiment. Note that the wavelengths of the five red laser beams emitted from five emitters 30 vary within a range of several nanometers in the present embodiment.

In semiconductor laser element 1 according to the present embodiment above, a plurality of laser beams of the same color are emitted from the plurality of emitters 30, but the plurality of laser beams include the laser beams with the different wavelengths, thus making it possible to suppress the speckle noise. In particular, the wavelengths of the two adjacent laser beams are different, thus making it possible to effectively suppress the speckle noise.

Further, in semiconductor laser element 1 according to the present embodiment, five points respectively corresponding to the wavelengths plotted include extreme values. In the present embodiment as illustrated in FIG. 2(d), the extreme values are located at positions corresponding to two portions including ridge parts Rl1 and Rr1. The extreme values in the distribution of the laser beam variation is not located at a position corresponding to the center (ridge part RC0 at the center) of laser array section 10 and are located at positions corresponding to places separated from the center of laser array section 10.

Consequently, interference caused by the overlapping of the plurality of laser beams no longer occurs at the central part of the visual field (for example, around the center of a screen surface) to which a human pays most attention, thus suppressing the speckle noise. Moreover, even upon the occurrence of the interference as a result of the overlapping of the plurality of laser beams, this occurs at a position separated from the central part. As a result, a human whose viewpoint is likely to be focused on the central part of the visual field is less likely to sense the speckle noise.

Moreover, providing the wavelength variation of the laser beams with the extreme values makes it possible to reduce a wavelength difference between the laser beam of the largest wavelength and the laser beam of the smallest wavelength both of which are included in the plurality of laser beams emitted from the plurality of emitters 30. Specifically, since a distribution of wavelengths of all the five laser beams do not monotonously increase or monotonously decrease, the wavelength difference between the laser beam of the largest wavelength and the laser beam of the smallest wavelength can be reduced more than in a case where the distribution of wavelengths of all the five laser beams monotonously increases or monotonously decreases. Consequently, the wavelength difference between the red laser beams emitted from the plurality of emitters 30 can be made small, thus making it possible to suppress color purity deterioration of the laser beams emitted from laser array section 10.

As described above, semiconductor laser element 1 according to the present embodiment enables laser beam emission without conspicuous speckle noise and without color purity deterioration.

Note that the center wavelength of the laser beam emitted from laser array section 10 including the plurality of emitters 30 is a wavelength of a laser beam emitted from emitter 30 defined as described below. More specifically, the aforementioned center wavelength refers to that of an n-th emitter (emitter 30) from the right end or the left end of laser array section 10 when the number of emitters 30 is odd-number represented by 2n−1. The aforementioned center wavelength refers to those of n-th- and (n+1)-th emitters (emitters 30) from the right end or the left end of laser array section 10 when the number of emitters (emitters 30) is an even number represented by 2n. Note that n is a natural number of 3 or larger. The same applies to the embodiments described below.

### Embodiment 2

Next, semiconductor laser element 2 according to Embodiment 2 will be described with reference to FIG. 4. In FIG. 4, (a) is a structure diagram of a laser beam emission end surface in semiconductor laser element 2 according to Embodiment 2, (b) is a diagram illustrating the widths of five emitters 30 in same semiconductor laser element 2, (c) is a diagram illustrating the effective refractive indices of the waveguide corresponding to five emitters 30 in same semiconductor laser element 2, and (d) is a diagram illustrating the oscillation wavelengths of laser beams emitted from five emitters 30 in same semiconductor laser element 2. Note that first electrode 51, second electrodes 52, and insulating layer 60 are omitted in FIG. 4(a).

Semiconductor laser element 2 according to the present embodiment and semiconductor laser element 1 according to Embodiment 1 differ from each other in the widths and intervals of five ridge parts 40.

More specifically, for five ridge parts 40 in Embodiment 1 described above, the four intervals between two adjacent ridge parts 40 are not all equal and include the different lengths. Moreover, the widths of five ridge parts 40 are all equal in Embodiment 1 described above.

On the contrary, for five ridge parts 40 in the present embodiment, the four intervals between two adjacent ridge parts 40 are all equal but the widths of five ridge parts 40 are not all equal and include different lengths, as illustrated in FIG. 4(a). The width of ridge part 40 can be easily varied by varying, for example, a pattern of a photomask.

As one example, in semiconductor laser element 2 according to the present embodiment, when the width of laser array section 10 (chip width) is 250 μm and the resonator length of laser array section 10 is 1 mm, where the widths of ridge parts Rl2, Rl1, RC0, Rr1, and Rr2 are defined as first width wl2, second width wl1, third width wc0, fourth width wr1, and fifth width wr2, respectively, wl2=5 μm, wl1=10 μm, wC0=5 μm, wr1=2 μm, and wr2=5 μm are provided. Note that all the four intervals between two adjacent ridge parts 40 are 50 μm.

Moreover, the positions and widths of emitters 30 correspond to the positions and widths of ridge parts 40, as described above. Consequently, in the present embodiment, three different lengths are provided as the widths of five ridge parts 40, and thus three different lengths are provided as the widths of five emitters 30 in correspondence with the widths of ridge parts 40 as illustrated in FIG. 4(b).

More specifically, as described above, the width of emitter 30 (emitter width) is almost equivalent to the length of a line linking together right and left corners at the lowermost part of ridge part 40 (two right and left points at the root). Thus, as is the case with the widths of five ridge parts 40, the widths of five emitters 30 are 5 μm, 10 μm, 5 μm, 2 μm, and 5 μm from the left end to the right end of laser array section 10 in the present embodiment.

Here, depending on the widths and lengths of emitters 30, refractive indices sensed by the beam propagating through a waveguide vary, and a refractive index (a refractive index sensed by the guided light on average) in view of a near-field distribution, i.e., a so-called effective refractive index Neff varies. More specifically, an increase in the width of emitter 30 increases the effective refractive index Neff while a decrease in the width of emitter 30 decreases the effective refractive index Neff. Thus, the effective refractive indices of the waveguide in laser array section 10 vary in conjunction with a variation in the length of the width of each emitter 30, as illustrated in FIG. 4(c).

As a result, when the oscillation wavelengths of the laser beams respectively emitted from five emitters 30 are plotted in correspondence with the positions of five emitters 30, the oscillation wavelengths of the laser beams vary in accordance with a distribution of the effective refractive indices of the waveguide as illustrated in FIG. 4(d). That is, the oscillation wavelengths of the five laser beams show an asymmetrical distribution.

More specifically, emitted from five emitters 30 corresponding to five ridge parts Rl2, Rl1, RC0, Rr1, and Rr2 are red laser beams of 631 nm, 632 nm, 631 nm, 630 nm, and 631 nm in order from the left end to the right end of laser array section 10.

As described above, the wavelength variation of the plurality of laser beams emitted from the plurality of emitters 30 is caused by the difference in the intervals between the plurality of ridge parts 40 (intervals between the plurality of emitters 30) in Embodiment 1 described above, but the wavelength variation of the plurality of laser beams emitted from the plurality of emitters 30 is caused by a difference in widths between the plurality of ridge parts 40 (widths between the plurality of emitters 30) in the present embodiment. More specifically, the wavelength variation of the five laser beams is caused by the difference in the width between five ridge parts 40 (width between five emitters 30). That is, the widths of the plurality of ridge parts 40 (the plurality of emitters 30) are varied depending on the position of laser array section 10 to thereby modulate the widths of ridge parts 40 (widths of emitters 30) in the present embodiment. Note that the wavelengths of the red laser beams emitted from five emitters 30 also vary within a range of several nanometers in the present embodiment.

As described above, also in semiconductor laser element 2 according to the present embodiment, a plurality of laser beams of the same color are emitted from the plurality of emitters 30, but as is the case with Embodiment 1, the plurality of laser beams include the laser beams with the different wavelengths, thus making it possible to suppress the speckle noise.

Further, also in semiconductor laser element 2 according to the present embodiment, five points respectively corresponding to the wavelengths plotted include extreme values. More specifically, as illustrated in FIG. 4(d), the extreme values are located at positions corresponding to the two portions, i.e., ridge parts Rl1 and Rr1. The extreme values in this distribution of beam variation are not located at a position corresponding to the center of laser array section 10 (ridge part RC0 at the center) and are located, at positions corresponding to places separated from the center of laser array section 10.

Consequently, also in semiconductor laser element 2 according to the present embodiment, as is the case with Embodiment 1, it is possible to make a laser beam emitted without conspicuous speckle noise and without color purity deterioration.

Note that the widths of five ridge parts 40 and the widths of five emitters 30 include the three difference lengths in the present embodiment, but are not limited thereto. The widths of five ridge parts 40 and the widths of five emitters 30 may all differ from each other. Moreover, excessively large widths of ridge parts 40 and excessively large widths of emitters 30 decrease the dependence of the widths of emitters 30 on the effective refractive indices, and thus it is recommended that the widths of ridge parts 40 are not excessively large. For example, the width of ridge part 40 may be approximately 100 μm at a maximum.

### Embodiment 3

Next, semiconductor laser element 3 according to Embodiment 3 will be described with reference to FIG. 5. In FIG. 5, (a) is a structure diagram of a laser beam emission end surface in semiconductor laser element 3 according to Embodiment 3, (b) is a diagram illustrating a distribution of off angles of the substrate surface in same semiconductor laser element 3, (c) is a diagram illustrating band gaps of active layer 13 in same semiconductor laser element 3, and (d) is a diagram illustrating the oscillation wavelengths of laser beams emitted from five emitters 30 in same semiconductor laser element 3. Note that first electrode 51, second electrodes 52, and insulating layer 60 are omitted in FIG. 5(a).

Semiconductor laser element 3 according to the present embodiment and semiconductor laser element 1 according to Embodiment 1 described above have different substrates 20. More specifically, the off angle of substrate 20 is constant in Embodiment 1 described above but the off angle of substrate 20 is not constant in the present embodiment as illustrated in FIG. 5(a). As a result, the layer structure of laser array section 10 formed on substrate 20 differs from that of Embodiment 1, as illustrated in FIG. 5(a).

Providing substrate 20 with an off angle varies the band gap of active layer 13 which makes crystal growth on substrate 20 and varies the oscillation wavelength of the laser beam in accordance with the off angle. For example, when using a GaAs substrate as substrate 20 and superposing an AlGaInP-based semiconductor layer as laser array section 10 on the GaAs substrate, providing inclination (off angle) with respect to surface orientation of the GaAs substrate and, for example, inclining the surface orientation of the GaAs substrate in a direction from surface 100 towards [011] varies the band gap of active layer 13 and varies the oscillation wavelength of the laser beam.

Thus, locating substrate 20 at a plurality of different off angles in correspondence with a plurality of emitters 30 makes it possible to vary the band gap of active layer 13 for each emitter 30, which can partially vary the oscillation wavelength of the laser beam. The oscillation wavelength of the laser beam is controlled by varying the off angle at the front surface of the GaAs substrate for each of five emitters 30 in the present embodiment.

Possible methods for varying the off angle of the front surface of the GaAs substrate for each emitter 30 are listed below.

The first method includes warping substrate 20. In this case, an AlAs layer is first grown on one of surfaces of the GaAs substrate whose both main surfaces form surface (100) and the GaAs substrate is warped by a linear expansion coefficient difference between the GaAs substrate and the AlAs layer. Direction <100> partially differs depending on the location of the GaAs substrate due to the warping of the GaAs substrate. Polishing another one of the surfaces of the warped GaAs substrate flat results in the appearance of the GaAs surface on the polished surface with the off angle varying depending on the location. The dependence of the off angle on the location is matched to the position of emitter 30.

The second method is a method performed by etching. In this case, resists respectively corresponding to emitters 30 are first formed on one of the surfaces of the GaAs substrate whose both surfaces form surface (100) and the aforementioned resists are inclined through dry etching. The resists are masked and the GaAs substrate is etched, thereby making it possible to provide a GaAs substrate having an off angle with respect to surface (100).

The off angle of the front surface of substrate 20 can be varied for each emitter 30 as described above. In the present embodiment, the off angles of substrate 20 respectively corresponding to five emitters 30 (inclinations from surface (100) of the GaAS substrate in direction [011]) are 9°, 6°, 3°, 0°, and 3°, respectively, as illustrated in FIG. 5(b).

Consequently, the band gap of active layer 13 varies for each emitter 30, as illustrated in FIG. 5 (c). More specifically, the bad gap of active layer 13 varies to provide size relationship opposite to that of off angle variation of substrate 20.

Here, since the oscillation wavelength of the laser beam increases with a decrease in the band gap of active layer 13, when the oscillation wavelengths of the laser beams respectively emitted from five emitters 30 are plotted in correspondence with the positions of five emitters 30, the oscillation wavelengths of the laser beams vary in accordance with a distribution of bad gaps of active layer 13 as illustrated in FIG. 5(d). That is, the five oscillation wavelengths of the laser beams show an asymmetrical distribution.

More specifically, emitted from five emitters 30 corresponding to five ridge parts Rl2, Rl1, RC0, Rr1, and Rr2 are red laser beams of 650 nm, 652 nm, 660 nm, 668 nm, and 660 nm in order from the left end to the right end of laser array section 10.

As described above, the wavelength variation of the plurality of laser beams emitted from the plurality of emitters 30 is caused by the difference in the intervals between the plurality of ridge parts 40 (intervals between emitters 30) in Embodiment 1, but the wavelength variation of the plurality of laser beams emitted from the plurality of emitters 30 is caused by a difference in the off angle of substrate 20 in the present embodiment. Specifically, the off angle of substrate 20 corresponding to the position of emitter 30 is varied to modulate the distribution of the oscillation wavelengths of the laser beams in the present embodiment. Note that the wavelengths of the red laser beams emitted from five emitters 30 vary within a range of several tens of nanometers.

Also in semiconductor laser element 3 according to the present embodiment, a plurality of laser beams of the same color are emitted from the plurality of emitters 30, but as is the case with Embodiment 1, the plurality of laser beams include the laser beams with the different wavelengths, thus making it possible to suppress the speckle noise.

Moreover, also in semiconductor laser element 2 according to the present embodiment, five points respectively corresponding to the wavelengths plotted include extreme values. More specifically, as illustrated in FIG. 5(d), the extreme values are located at positions corresponding to the two portions, i.e., ridge parts Rl1 and Rr1. The extreme values in a distribution of the laser beam variation are not located at a position corresponding to the center (ridge part RC0 at the center) of laser array section 10 and are located at positions corresponding to places separated from the center of laser array section 10.

Consequently, also in semiconductor laser element 2 according to the present embodiment, as is the case with Embodiment 1, it is possible to emit laser beams without conspicuous speckle noise and without color purity deterioration.

### Embodiment 4

Next, semiconductor laser element 4 according to Embodiment 4 will be described with reference to FIG. 6. In FIG. 6, (a) is a structure diagram of a laser beam emission end surface in semiconductor laser element 4 according to Embodiment 4, (b) is a diagram illustrating a distribution of inclination angles of ridge parts 40 in same semiconductor laser element 4, (c) is a diagram illustrating effective refractive indices of the waveguide corresponding to five emitters 30 in same semiconductor laser element 4, and (d) is a diagram illustrating the oscillation wavelengths of laser beams emitted from five emitters 30 in same semiconductor laser element 4. Note that first electrode 51, second electrodes 52, and insulating layer 60 are omitted in FIG. 6(a).

Semiconductor laser element 4 according to the present embodiment and semiconductor laser element 1 according to Embodiment 1 described above differ from each other in inclination angles (ridge angles) of five ridge parts 40.

Here, the inclination angle of ridge part 40 can be defined as an average ridge angle as described below. More specifically, where two lines linking together right and left corners at the lowermost part of ridge part 40 (two right and left points at the root) and right and left corners at the uppermost part (two right and left points at the summit), that is, two lines including a line linking together point P1 and point P3 and a line linking together point P2 and point P4 form angles θ1 and 02, respectively, in a direction normal to the surface of active layer 13, an inclination angle θr of ridge part 40 is represented by (θ1+θ2)/2.

In Embodiment 1 described above, the inclination angles of five ridge part 40 are all equal, but all the inclination angles θr of five ridge parts 40 are not equal and include different angles as illustrated in FIG. 6(a) in the present embodiment. That is, the inclination angles θr of five ridge parts 40 are modulated.

As one example, the inclination angles θr of ridge parts Rl2, Rl1, RC0, Rr1, and Rr2 of five ridge parts 40 are set at 10°, 20°, 10°, 0°, and 10° from the left end to the right end of laser array section 10. Consequently, a distribution of the inclination angles θr of ridge parts 40 varies as illustrated in FIG. 6(b). Note that absolute values of the right and left inclination angles θr in each ridge part 40 are equal.

Here, the effective refractive indices of the waveguide vary depending on the inclination angles θr of ridge parts 40. More specifically, an increase in the inclination angle θr of ridge part 40 with respect to the same ridge width widens the effective width of emitter 30, resulting in an increase in the effective refractive index. A decrease in the inclination angle θr of ridge part 40 narrows the effective width of emitter 30, resulting in a decrease in the effective refractive index. Thus, the effective refractive indices of the waveguide in laser array section 10 vary in conjunction with the variation in the inclination angle θr of ridge part 40, as illustrated in FIG. 6(c).

As a result, when the oscillation wavelengths of the laser beams respectively emitted from five emitters 30 are plotted in correspondence with the positions of five emitters 30, the oscillation wavelengths of the laser beams vary in accordance with the distribution of effective refractive indices of the waveguide as illustrated in FIG. 6(d). That is, the oscillation wavelengths of the five laser beams show an asymmetrical distribution.

More specifically, emitted from five emitters 30 corresponding to five ridge parts Rl2, Rl1, RC0, Rr1, and Rr2 are red laser beams of 631 nm, 632 nm, 631 nm, 630 nm, and 631 nm in order from the left end to the right end of laser array section 10.

As described above, the wavelength variation of the plurality of laser beams emitted from the plurality of emitters 30 is caused by the difference in the intervals between the plurality of ridge parts 40 (intervals between emitters 30) in Embodiment 1 described above but the wavelength variation of the plurality of laser beams emitted from the plurality of emitters 30 is caused by a difference in the inclination angles (average ridge angles) of ridge parts 40 in the present embodiment. That is, the respective inclination angles of the plurality of ridge parts 40 are varied to modulate the practical widths of emitters 30, thereby modulating the distribution of the oscillation wavelengths of the laser beams.

As described above, also in semiconductor laser element 4 according to the present embodiment, the plurality of laser beams of the same color are emitted from the plurality of emitters 30 but, as is the case with Embodiment 1, the plurality of laser beams include the laser beams with the different wavelengths, thus making it possible to suppress the speckle noise.

Further, also in semiconductor laser element 4 according to the present embodiment, five points respectively corresponding to the wavelengths plotted include extreme values. More specifically, as illustrated in FIG. 6(d), the extreme values are located at positions corresponding to two portions, i.e., ridge parts Rl1 and Rr1. The extreme values in the distribution of the laser beam variation are not located at a position corresponding to the center of laser array section 10 (ridge part RC0 at the center) and are located at positions corresponding to places separated from the center of laser array section 10.

Consequently, also in semiconductor laser element 4 according to the present embodiment, as is the case with Embodiment 1, it is possible to emit laser beams without conspicuous speckle noise and without color purity deterioration.

Note that the inclination angle θr of each ridge part 40 may be varied, for example, by irradiating a laser beam from an outside at time of dry etching upon forming ridge part 40 to thereby vary the temperature of each ridge part 40.

### Embodiment 5

Next, semiconductor laser device 100 according to Embodiment 5 will be described with reference to FIGS. 7 and 8. FIG. 7 is a perspective view of semiconductor laser device 100 according to Embodiment 5. In FIG. 8, (a) is a diagram illustrating a structure of a laser beam emission end surface in semiconductor laser device 100 according to Embodiment 5, (b) is a diagram illustrating a temperature distribution of cooling water in same semiconductor laser device 100, (c) is a diagram illustrating a temperature distribution of active layer 13 in same semiconductor laser element 4, and (d) is a diagram illustrating the oscillation wavelengths of laser beams emitted from five emitters 30 in same semiconductor laser element 4. Note that first electrode 51, second electrodes 52, and insulating layer 60 are omitted in FIG. 8(a).

As illustrated in FIGS. 7 and 8(a), semiconductor laser device 100 according to the present embodiment includes semiconductor laser element 5, submount 110, and water-cooled heat sink 120.

As is the case with semiconductor laser element 1 according to Embodiment 1 described above, semiconductor laser element 5 according to the present embodiment includes: substrate 20; and laser array section 10 located on substrate 20 and having a plurality of emitters 30 (light emitting parts) which are arranged next to each other and which emit laser beams.

Laser array section 10 is a laminate having first cladding layer 11, first guiding layer 12, active layer 13, second guiding layer 14, second cladding layer 15, and contact layer 16 laminated in order just mentioned.

Laser array section 10 has a ridge waveguide structure having ridge parts 40. More specifically, as is the case with Embodiment 1 described above, laser array section 10 has a plurality of ridge parts 40. Also in the present embodiment, five ridge parts 40 are formed in laser array section 10. That is, five emitters 30 are provided in correspondence with five ridge parts 40 in laser array section 10.

Moreover, intervals between two adjacent ridge parts 40 (ridge intervals), respective widths of ridge parts 40 (ridge widths), and respective inclination angles of ridge parts 40 are all equal in five ridge parts 40 in the present embodiment. Therefore, intervals between two adjacent emitters 30 (emitter intervals) and respective widths of emitters 30 (emitter widths) are all equal in five emitters 30. As one example, the ridge intervals and the emitter intervals are all 100 μm, the ridge widths and the emitter widths are all 10 μm, and the inclination angles of ridge parts 40 are all 15 degrees.

Note that as is the case with semiconductor laser element 1 according to Embodiment 1 described above, first electrode 51, second electrodes 52, and insulating layer 60 are further formed in semiconductor laser element 5.

Semiconductor laser element 5 according to the present embodiment is configured to emit blue laser beams. In this case, semiconductor laser element 5 which emits blue laser beams can be obtained by using a semiconductor substrate formed of a GaN substrate as substrate 20 and forming laser array section 10 with a semiconductor material of a group III nitride semiconductor represented by AlₓGa_{y}In_{1-x-y}N (where 0≤x, y≤1, 0≤x+y≤1).

More specifically, an n-type GaN substrate having a thickness of 80 μm and surface (0001) as a main surface can be used as substrate 20. In this case, as laser array section 10 formed of the GaN-based semiconductor material, it is possible to use an n-type cladding layer as first cladding layer 11, use an undoped n-side guiding layer as first guiding layer 12, use an undoped active layer as active layer 13, use an undoped p-side guiding layer as second guiding layer 14, use a p-type cladding layer as second cladding layer 15, and use a p-type contact layer as contact layer 16.

As one example, first cladding layer 11 is formed of n-Al_{0.2}Ga_{0.8}N with a film thickness of 0.5 μm, first guiding layer 12 is formed of u-GaN with a film thickness of 0.1 μm, active layer 13 is formed of u-In_{0.3}Ga_{0.7}N with a film thickness of 9 μm, second guiding layer 14 is formed of u-GaN with a film thickness of 0.1 μm, second cladding layer 15 is formed of p-Al_{0.2}Ga_{0.8}N with a film thickness of 0.3 μm, and contact layer 16 is formed of p-GaN with a film thickness of 0.1 μm. Note that first electrode 51 is an n-side electrode and second electrodes 52 are p-side electrodes and the both are each formed of a metal material such as Cr, Ti, Ni, Pd, Pt, or Au.

Note that an AlGaN overflow suppression layer may be inserted between active layer 13 and second guiding layer 14 or between second guiding layer 14 and second cladding layer 15 to avoid electronic leakage from active layer 13.

Semiconductor laser element 5 configured as described above is mounted on submount 110. In the present embodiment, a plate-like submount formed of SiC with a horizontal length of 2 mm, a vertical length of 1.5 mm, and a thickness of 0.3 mm is used as submount 110. Submount 110 is arranged in water-cooled heat sink 120.

Water-cooled heat sink 120 cools semiconductor laser element 5. Water-cooled heat sink 120 cools laser array section 10 in particular. Water-cooled heat sink 120 is, for example, a metal body having a flow path through which cooking water flows. For example, copper, aluminum, or stainless steel can be used as a material of the metal body. A plate-like heat sink of copper with a horizontal length of 10 mm, a vertical length of 8 mm, and a thickness of 5 mm is used as water-cooled heat sink 120 in the present embodiment.

The cooling water in water-cooled heat sink 120 flows inside of water-cooled heat sink 120 one way. In the present embodiment, the water-cooled heat sink is provided with two linear flow paths separated from each other, and the cooling water linearly flows from one of the flow paths to the other. Moreover, the cooling water in water-cooled heat sink 120 flows in a direction in which emitters 30 of laser array section 10 are arrayed. That is, the cooling water flows in a direction (a stripe direction) orthogonal to a direction in which ridge parts 40 extend. That is, the cooling water flows in the direction (stripe direction) orthogonal to the direction in which ridge parts 40 extend. Moreover, the cooling water in water-cooled heat sink 120 flows through each of the two flow paths, for example, at a flow rate of 2 L per minute.

In semiconductor laser device 100 configured as described above, the temperature of the cooling water on an inlet side is low but the cooling water absorbs heat generated by emitters 30 as the cooling water flows, so that the temperature of the cooling water becomes increasingly higher towards the downstream side. That is, the temperature of the cooling water flowing through water-cooled heat sink 120 is low on the inlet side and thus the aforementioned cooling water has high cooling capability while the temperature of the cooling water flowing through water-cooled heat sink 120 increases due to the absorption of the heat generated in emitters 30 on an outlet side of the cooling water and thus the cooling water has low cooling capability. As a result, the temperature of the cooling water has a temperature gradient as illustrated in FIG. 8(b).

Such a temperature gradient of the cooling water deteriorates the effect of cooling by the cooling water on a downstream side of the cooling water (cooling water outlet side) in laser array section 10. Consequently, a place of laser array section 10 where a greatest amount of heat is stored shifts from the central part of laser array section 10 to the cooling water outlet side, which can modulate the temperature distribution of laser array section 10.

As a result, for example, the temperature of active layer 13 varies as illustrated in FIG. 8(c). Consequently, where the oscillation wavelengths of the laser beams respectively emitted from five emitters 30 are plotted in correspondence with positions of five emitters 30, the oscillation wavelengths of the laser beams vary in accordance with the temperature distribution of active layer 13 as illustrated in FIG. 8(d). That is, the oscillation wavelengths of the five laser beams show an asymmetrical distribution.

More specifically, emitted from five emitters 30 corresponding to five ridge parts Rl2, Rl1, RC0, Rr1, and Rr2b are blue laser beams of 450 nm, 451 nm, 450 nm, 449 nm, and 448 nm in order from the left end to the right end of laser array section 10.

As described above, the wavelength variation of the plurality of laser beams emitted from the plurality of emitters 30 is caused by a difference in the temperature of the cooling water in water-cooled heat sink 120 in the present embodiment. Note that the wavelengths of the blue laser beams emitted from five emitters 30 vary within a range of several nanometer in the present embodiment.

As described above, also in semiconductor laser device 100 according to the present embodiment, a plurality of laser beams of the same color are emitted from the plurality of emitters 30, and as is the case with the other embodiments, the plurality of laser beams include the laser beams with the different wavelengths, thus making it possible to suppress the speckle noise.

Further, also in semiconductor laser device 100 according to the present embodiment, five points respectively corresponding to the wavelengths plotted include extreme value. More specifically, as illustrated in FIG. 8(d), the extreme values are located at a position corresponding to ridge part Rl1. The extreme value in the distribution of the laser beam variation is not located at a position corresponding to the center of laser array section 10 (ridge part RC0 at the center) and is located at a positions corresponding to a place separated from the center of laser array section 10.

Consequently, as is the case with the other embodiments, it is also possible in semiconductor laser device 100 according to the present embodiment to emit laser beams without conspicuous speckle noise and without color purity deterioration.

Moreover, the temperature distribution of the cooling water illustrated in FIG. 8(b) can be adapted to a desired temperature distribution by adjusting the flow rate of the cooling water flowing through water-cooled heat sink 120 in the present embodiment. That is, the distribution of the oscillation wavelengths of the laser beams as illustrated in FIG. 8(d) can be realized through appropriate adjustment of the flow rate of the cooling water.

Moreover, a direction in which the cooling water flows is parallel to a direction in which emitters 30 are arrayed in the present embodiment, but the direction in which the cooling water flows is not necessarily parallel to the direction in which emitters 30 are arrayed and may be inclined with respect to the direction in which emitters 30 are arrayed.

For example, as illustrated in FIG. 9, where an angle formed by the direction in which the cooling water flows (heat dissipation direction) and the direction in which emitters 30 are arrayed is a and heat dissipation capability in the direction in which the cooling water flows is F, a heat dissipation component Fh (heat dissipation component in a horizontal direction) in the direction in which emitters 30 are arrayed is represented by (Expression 1) below.

[Math 1]

F h∝F·cos α (Expression 1)

Here, even when the heat dissipation effect deteriorates by 10%, the heat sink function is typically maintained, thus achieving (Expression 2) below.

[Math 2]

F·cos α=F·(100%−10%) (Expresion 2)

Therefore, the direction in which the cooling water flows satisfies (Expression 2). That is, with an inclination of α≤approximately 26 degrees, it is possible to control the wavelength of the laser beam emitted from each emitter 30 based on a temperature variation of the cooling water. That is, “the cooling water flows along the direction in which emitters 30 are arrayed” may include an inclination of up to approximately 26 degrees, and the aforementioned effect can be provided when the inclination in the direction in which the cooling water flows with respect to the direction in which emitters 30 are arrayed is approximately up to 26 degrees.

Note that the ridge intervals, ridge widths, inclination angles, composition, etc. of ridge parts 40 are all equal in the present embodiment but may include different values as is the case with the other embodiments. Moreover, the same applies to emitters 30; the emitter intervals and emitter widths of emitters 30 are all equal but may include different values. That is, the semiconductor laser elements according to Embodiments 1 to 4 may be used as the semiconductor laser element according to the present embodiment.

### Embodiment 6

Next, projector 200 according to Embodiment 6 will be described with reference to FIG. 10. FIG. 10 is a schematic diagram of projector 200 according to Embodiment 6.

As illustrated in FIG. 10, projector 200 is one example of an image display device using a semiconductor laser. Used as light sources in projector 200 according to the present embodiment are: for example, semiconductor laser 201R which emits a red laser beam; semiconductor laser 201G which emits a blue laser beam; and semiconductor laser 201B which emits a green laser beam. Moreover, for example, the semiconductor laser elements or the semiconductor laser device according to Embodiments 1 to 5 described above are used as semiconductor laser 201R, semiconductor laser 201G, and semiconductor laser 201B.

Projector 200 includes lens 210R, lens 210G, lens 210B, mirror 220R, dichroic mirror 220G, dichroic mirror 220B, spatial modulation element 230, and projection lens 240.

Lens 210R, lens 210G, and lens 210B are, for example, collimating lenses and are respectively arranged in front of semiconductor laser 201R, semiconductor laser 201G, and semiconductor laser 201B.

Mirror 220R reflects the red laser beam emitted from semiconductor laser 201R. Dichroic mirror 220G reflects the green laser beam emitted from semiconductor laser 201G and permits the transmission of the red laser beam emitted from semiconductor laser 201R. Dichroic mirror 220B reflects the blue laser beam emitted from semiconductor laser 201B and permits the transmission of the red laser beam emitted from semiconductor laser 201R and also permits the transmission of the blue laser beam emitted from semiconductor laser 201B.

Spatial modulation element 230 forms a red image, a green image, and a blue image by use of the red laser beam emitted from semiconductor laser 201R, the green laser beam emitted from semiconductor laser 201G, and the blue laser beam emitted from semiconductor laser 201B in accordance with an input image signal inputted to projector 200. For example, any of a liquid crystal panel and a digital mirror device (DMD) using a micro electrical mechanical system (MEMS) can be used as spatial modulation element 230.

Projection lens 240 projects, on screen 250, the images formed in spatial modulation element 230.

In projector 200 configured as described above, the laser beams emitted from semiconductor laser 201R, semiconductor laser 201G, and semiconductor laser 201B are transformed into substantially parallel beams at lens 210R, lens 210G, and lens 210B and then enter mirror 220R, dichroic mirror 220G, and dichroic mirror 220B.

Mirror 220R reflects the red laser beam emitted from semiconductor laser 201R in a direction of 45 degrees. Dichroic mirror 220G permits the transmission of the red laser beam emitted from semiconductor laser 201R and reflected on mirror 220R and also reflects the green laser beam emitted from semiconductor laser 201G in a direction of 45 degrees. Dichroic mirror 220B permits the transmission of the red laser beam emitted from semiconductor laser 201R and reflected on mirror 220R and the green laser beam emitted from semiconductor laser 201G and reflected on dichroic mirror 220G and also reflects the blue laser beam emitted from semiconductor laser 201B in a direction of 45 degrees.

The red, green, and blue laser beams reflected by mirror 220R, dichroic mirror 220G, and dichroic mirror 220B enter spatial modulation element 230 in a time-division manner (for example, sequential switching red→green→blue occurs in a cycle of 120 Hz). In this case, an image for a red color is displayed upon the entrance of the red laser beam, an image for a green color is displayed upon the entrance of the green laser beam, and an image for a blue color is displayed upon the entrance of the blue laser beam in spatial modulation element 230.

As described above, the red, green, and blue laser beams subjected to the spatial modulation by spatial modulation element 230 turn into a red image, a green image, and a blue image and are projected onto screen 250 through projection lens 240. In this case, each of the red image, the green image, and the blue image projected on screen 250 in a time-division manner is single-colored but switches at a high speed, so that they are recognized as an image of the mixed colors of the aforementioned images, that is, a color image to human eyes.

As described above, the semiconductor laser elements or the semiconductor laser device according to Embodiments 1 to 5 described above are used as semiconductor laser 201R, semiconductor laser 201G, and semiconductor laser 201B in projector 200 according to the present embodiment. That is, a semiconductor laser element or a semiconductor laser device is used which is capable of emitting a plurality of laser beams without conspicuous speckle noise and without color purity deterioration.

Consequently, no speckle noise is generated at the central part of screen 250. Moreover, even if the speckle noise is generated as a result of laser beam interference, the speckle noise is generated at a position separated from the central part of screen 250. Therefore, a person who views an image projected on screen 250 is less likely to sense the speckle noise. In addition, the color purity improves, which therefore never deteriorates the sharpness of the image projected on screen 250.

### Variations

The semiconductor laser elements and the semiconductor laser device according to the present disclosure have been described above based on the embodiments, but the present disclosure is not limited to the embodiments described above.

For example, semiconductor laser element 1 which emits red laser beams has been illustrated in Embodiments 1 to 4 above, but blue laser beams may be emitted in Embodiments 1 to 4 described above. In this case, a semiconductor laser element can be realized with the same material as that of Embodiment 5.

Moreover, semiconductor laser element 5 which emits blue laser beams has been illustrated in Embodiment 5 above, but semiconductor laser element 5 may be configured to emit red laser beams in Embodiment 5 described above. In this case, the semiconductor laser element can be realized with the same material as that of Embodiment 1.

Moreover, the semiconductor laser element may be configured to emit green laser beams in Embodiment 1 to 5 described above. In case of the semiconductor laser element which emits green laser beams, for example, a GaN substrate may be used as substrate 20 and laser array section 10 may be formed of a semiconductor material of a group III nitride semiconductor represented by AlₓGa_{y}In_{1-x-y}N (where 0≤x, y≤1, and 0≤x+y≤1). More specifically, it is possible to use an n-type GaN substrate as substrate 20, use n-Al_{0.2}Ga_{0.8}N as first cladding layer 11, use u-GaN as first guiding layer 12, use u-In_{0.18}Ga_{0.82}N as active layer 13, use u-GaN as second guiding layer 14, use p-Al_{0.2}Ga_{0.8}N as second cladding layer 15, and use p-GaN as contact layer 16.

Moreover, the semiconductor laser elements having a ridge waveguide structure are used in Embodiments 1 to 6 described above although the present disclosure is not limited to such semiconductor laser elements.

More specifically, semiconductor laser element 1A may be adopted in which no ridge part is formed as illustrated in FIG. 11. In semiconductor laser element 1A, emitters 30 are formed with only second electrodes 52a and 52b which are divided. In semiconductor laser element 1A configured as described above, a refractive index difference in a horizontal direction of emitters 30 is provided by a difference in an imaginary part of a reflective index generated by a gain through current injection and thus is referred to as a gain guide type. A semiconductor laser element of a gain guide type has a simpler structure and has laser array section 10 which can be fabricated at lower cost than a semiconductor laser element of a refractive index waveguide type.

Note that a middle point of each emitter 30 in semiconductor laser element 1A of the present variation illustrated in FIG. 11 is a middle point between right and left ends of second electrode 52a. More specifically, as illustrated in FIG. 12, where coordinates at the left end of second electrode 52a on the emission end surface is P6(x3, y3) and coordinates at the right end of second electrode 52a is P7(x4, y4), the middle point of each emitter 30 is located at a point represented by coordinates P8((x3+x3)/2, (y4+y4)/2).

Moreover, the width of emitter 30 (emitter width) in the present variation is almost equivalent to the length of a line linking together the right and left ends of second electrode 52a. More specifically, the width of emitter 30 in FIG. 12 is a length of a line linking together points P6 and P7 and is thus represented by {(x3−x4)2+(y3−y4)2}^{1/2}.

Moreover, as another example of the semiconductor laser element in which no ridge part is formed, semiconductor laser element 1B with a structure illustrated in FIG. 13 may be provided. In semiconductor laser element 1B, after dividing second cladding layer 15, embedding layers 17 may be formed between adjacent second cladding layers 15. Embedding layers 17 are of a conductivity type different from that of second cladding layers 15 and also have a lower refractive index than second cladding layers 15. Note that contact layer 16 is formed over entire surfaces of second cladding layers 15 and embedding layers 17. Moreover, second electrode 52 is also formed over an entire surface of contact layer 16. Since second cladding layers 15 and embedding layers 17 are of different conductivity types (for example, second cladding layers 15 is p-type semiconductor layers and embedding layers 17 are n-type semiconductor layers), inversed bias is applied to a pn junction in an operating state, no current flows in embedding layers 17, and the injected current is confined to only second cladding layers 15. Consequently, beams generated in emitters 30 are confined in a horizontal direction of the substrate due to the refractive index difference between second cladding layers 15 and embedding layers 17. That is, semiconductor laser element 1B according to the present variation is of a refractive index waveguide type as is the case with semiconductor laser element 1 according to Embodiment 1 described above. Semiconductor laser element 1B configured as described above has a large contact area between contact layer 16 and second electrodes 52, which therefore enables low contact resistance (in other words, low voltage operation).

Note that in semiconductor laser element 1B of the present variation illustrated in FIG. 13, a middle point of each emitter 30 is located at a middle point of a line linking together right and left corners at the lowermost part of embedding layer 17 provided for single emitter 30. More specifically, as illustrated in FIG. 14, where coordinates at the left corner at the lowermost part of embedding layer 17 on the emission end surface is P9(x5, y5) and coordinates at the right corner at the lowermost part of embedding layer 17 is P10(x6, y6), the middle point of each emitter 30 is located at a point represented by P11((x5+x6)/2, (y5+y6)/2).

Moreover, the width of emitter 30 (emitter width) in the present variation is almost equivalent to the length of a line linking together the right and left corners at the lowermost part of embedding layer 17. More specifically the width of emitter 30 in FIG. 14 is the length of a line linking together points P9 and 10 and is thus represented by {(x5−x6)2+(y5−y6)²}^{1/2}.

Note that in a case where any of the semiconductor laser elements, according to Embodiments 1 to 4 described above, which emit red laser beams is applied as embedding layer 17 in semiconductor laser element 1B of the present variation illustrated in FIG. 13, n-(Al_{0.6}Ga_{0.4})_{0.5}In_{0.5}P can be provided. In a case where the semiconductor laser element, according to Embodiment 5, which emits blue laser beams is applied and in a case where a semiconductor laser element which emits green laser beams is applied, embedding layer 17 may be of n-GaN.

Moreover, semiconductor laser elements 1A and 1B illustrated in FIGS. 11 and 12 have been illustrated as the semiconductor laser elements in which no ridge part is formed, but the semiconductor laser element in which no ridge part is formed may be a vertical cavity surface emitting laser (VCSEL) or the like other than the semiconductor laser elements described above.

Moreover, the number of ridge parts 40 is five in Embodiments 1 to 6 described above, although the present disclosure is not limited to this number. For example, the number of ridge parts 40 may be six or more. That is, the number of emitters 30 is also not limited to five. For example, the numbers of ridge parts 40 and emitters 30 may be 20. Consequently, it is possible to realize a semiconductor laser element with high output over 1 W (for example, 100 W class).

Moreover, a case where the semiconductor laser elements and the semiconductor laser device according to Embodiments 1 to 5 described above are used as light sources of a projector is illustrated in Embodiment 6 described above, but the semiconductor laser elements and the semiconductor laser device according to Embodiments 1 to 5 described above are not limited to the light sources of the projector and may be used as light sources of a different device.

Moreover, the present disclosure also includes: a mode obtained by making various modification, conceivable to those skilled in the art, to the embodiments described above; and a mode realized by combining the components and the functions in each of the embodiments in a desired manner without departing from the spirits of the present disclosure.

### INDUSTRIAL APPLICABILITY

The semiconductor laser elements and the semiconductor laser device according to the present disclosure can be used as light sources of, for example, an image display device such as a projector and are effective especially as light sources of a device which requires relatively high optical output.

### REFERENCE MARKS IN THE DRAWINGS

1, 1A, 1B, 2, 3, 4, 5 semiconductor laser element
10 laser array section
10a first end surface
10b second end surface
10L laser beam
11 first cladding layer 11
12 first guiding layer
13 active layer
14 second guiding layer
15 second cladding layer
16 contact layer
17 embedding layer
20 substrate
30 emitter
40 ridge part
51 first electrode
52, 52a second electrode
60 insulating layer
100 semiconductor laser device
110 submount
120 water-cooled heat sink
200 projector
201R, 201G, 201B semiconductor laser
210R, 210G, 210B lens
220R mirror
220G, 220B dichroic mirror
230 spatial modulation element
240 projection lens
250 screen

1. A semiconductor laser element, comprising:
a substrate; and
a laser array section located above the substrate, the laser array section having a plurality of light emitting parts which are arranged next to each other and which emit laser beams, wherein
when wavelengths of the laser beams respectively emitted from the plurality of light emitting parts are plotted in correspondence with positions of the plurality of light emitting parts, among a plurality of points respectively corresponding to the wavelengths plotted, the point with an extreme value is not located at a position corresponding to a center of the laser array section and is located at a position corresponding to a place separated from the center of the laser array section.

2. The semiconductor laser element according to claim 1, wherein
intervals between two adjacent light emitting parts included in the plurality of light emitting parts include different lengths.

3. The semiconductor laser element according to claim 1, wherein
respective widths of the plurality of light emitting parts include different lengths.

4. The semiconductor laser element according to claim 1, wherein
the substrate has a plurality of different off angles in correspondence with the plurality of light emitting parts.

5. The semiconductor laser element according to claim 1, wherein
the laser array section has a ridge waveguide structure having a plurality of ridge parts respectively corresponding to the plurality of light emitting parts, and
inclination angles of the plurality of ridge parts include different angles.

6. A semiconductor laser device, comprising:
a substrate;
a laser array section located above the substrate, the laser array section having a plurality of light emitting parts which are arranged next to each other and which emit laser beams; and
a water-cooled heat sink which cools the laser array section, wherein
when wavelengths of the laser beams respectively emitted from the plurality of light emitting parts are plotted in correspondence with positions of the plurality of light emitting parts, among a plurality of points respectively corresponding to the wavelengths plotted, the point with an extreme value is not located at a position corresponding to a center of the laser array section and is located at a position corresponding to a place separated from the center of the laser array section.

7. The semiconductor laser device according to claim 6, wherein
temperatures of cooling water in the water-cooled heat sink varies depending on the positions of the plurality of light emitting parts.

8. The semiconductor laser device according to claim 6, wherein
the cooling water in the water-cooled heat sink flows along a direction in which the plurality of light emitting parts are arranged next to each other.
